(19) United States
(12) Patent Application Publication
(10) Pub. No.: US 2025/0227970 A1
(43) Pub. Date: Jul. 10, 2025

(54) High-voltage semiconductor structure and the forming method thereof

(71) Applicant: UNITED MICROELECTRONICS CORP., Hsinchu City (TW)

(72) Inventor: Kai-Kuen Chang, Hsinchu City (TW)

(73) Assignee: UNITED MICROELECTRONICS CORP., Hsinchu City (TW)

(21) Appl. No.: 18/421,933

(22) Filed: Jan. 24, 2024

(30) Foreign Application Priority Data
Jan. 4, 2024 (TW) 113100423

(51) Int. Cl. H01L 29/08; H01L 29/06; H01L 29/66; H01L 29/78

(52) U.S. Cl. CPC H10D 62/152; H10D 30/0281; H10D 30/65; H10D 62/107; H10D 62/116

(57) ABSTRACT

The invention provides a high-voltage semiconductor structure, which comprises a substrate with a first conductivity type, a gate structure located on the substrate, a source drift region and a drain drift region located in the substrate at two sides of the gate structure respectively, wherein the source drift region and the drain drift region respectively comprise a first part and a second part when viewed from a top, the width of the first part is smaller than that of the second part, and the first part is directly connected with the second part. The source drift region and the drain drift region are T-shaped when viewed from the top view, and the source drift region and the drain drift region have a second conductivity type.

### BACKGROUND OF THE INVENTION

### 1. Field of the Invention

The present invention relates to a semiconductor element, and more specifically, to a field drift metal oxide semiconductor (FDMOS) element.

### 2. Description of the Prior Art

Metal-oxide-semiconductor (MOS) transistors are widely used in the semiconductor industry because their power consumption is lower than that of traditional transistors and they can be fabricated at high density. When an appropriate voltage is input, MOS transistor can be used as a switch to control the current through the element. In high-voltage circuits, such as input and output terminals of electronic equipment, field drift metal oxide semiconductor (FDMOS) transistors are widely used because they can withstand heavy loads.

However, the prior art FDMOS element has several disadvantages. For example, the traditional FDMOS device may have a parasitic field device, which will turn on when the operating voltage exceeds about 10V, resulting in unstable circuit model. With the development of integrated circuits, it is becoming more and more important to improve field drift metal oxide semiconductor (FDMOS) transistors.

### SUMMARY OF THE INVENTION

The main purpose of the present invention is to provide an improved high-voltage semiconductor structure, so as to solve the above-mentioned shortcomings of the prior art.

The invention provides a high-voltage semiconductor structure, which comprises a substrate with a first conductivity type, a gate structure located on the substrate, a source drift region and a drain drift region located in the substrate at two sides of the gate structure respectively, wherein the source drift region and the drain drift region respectively comprise a first part and a second part when viewed from the top, the width of the first part is smaller than the width of the second part, and the first part is directly connected with the second part, the source drift region and the drain drift region are T-shaped from the top view, and the source drift region and the drain drift region have a second conductivity type.

The invention also provides a method for forming a high-voltage semiconductor structure, which comprises the following steps: providing a substrate with a first conductivity type, forming a gate structure on the substrate, forming a source drift region and a drain drift region which are respectively located in the substrate at two sides of the gate structure, wherein the source drift region and the drain drift region respectively comprise a first part and a second part when viewed from the top, and the width of the first part is smaller than the width of the second part. The first part is directly connected with the second part, and the source drift region and the drain drift region are T-shaped when viewed from the top, and the source drift region and the drain drift region have a second conductivity type.

The invention is characterized by providing a high-voltage semiconductor structure and a manufacturing method thereof. The source drift region and the drain drift region contained therein have a shape similar to a T-shape from the top view or have a notched corner. Because of the notched corner, the effective channel length between the source drift region and the drain drift region becomes longer at the boundary part parallel to the gate doped region, so that Kink effect can be reduced without forming additional doped regions, and the stability of the high-voltage semiconductor structure and the process yield can be improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 is a schematic diagram of the top layout of a high-voltage semiconductor structure according to a first embodiment of the present invention.

FIG. 2 is a schematic cross-sectional view of the high-voltage semiconductor structure according to FIG. 1 taken along section line A-A′.

FIG. 3 is a schematic layout diagram of a high-voltage semiconductor structure according to a second embodiment of the present invention.

FIG. 4 is a schematic cross-sectional view of the high-voltage semiconductor structure according to FIG. 3 taken along section line B-B′.

FIG. 5 is a schematic cross-sectional view of the high-voltage semiconductor structure according to FIG. 3 taken along section line C-C′.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

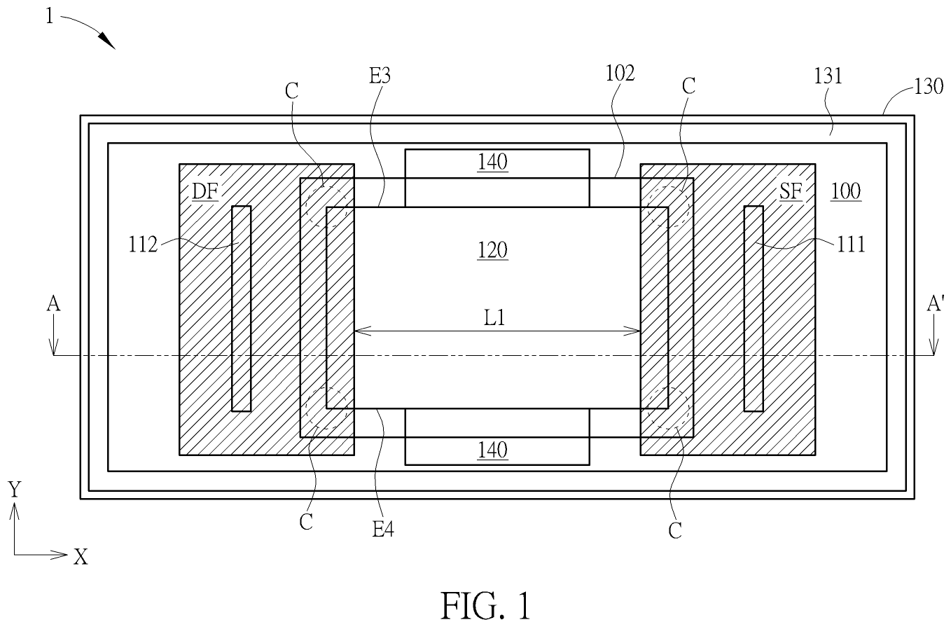

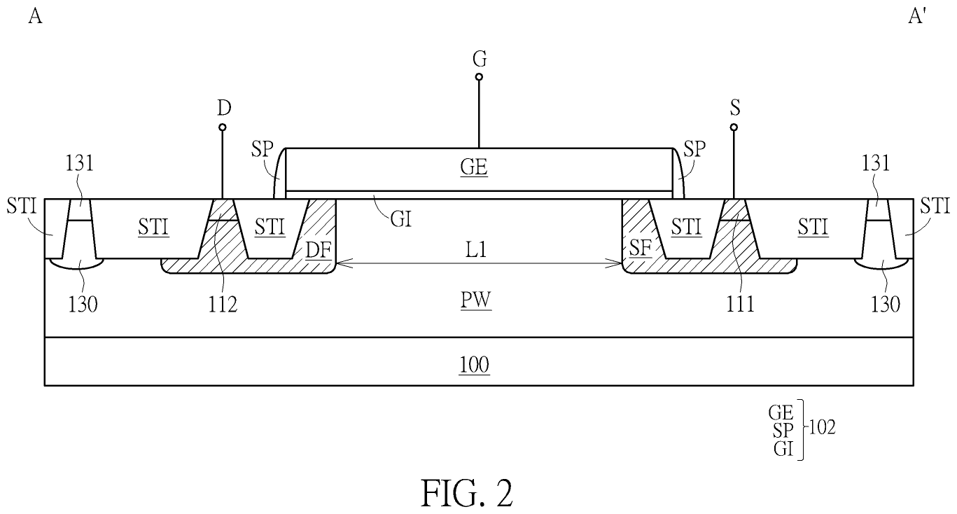

Please refer to FIGS. 1 to 2, wherein, FIG. 1 is a schematic layout diagram of a high-voltage semiconductor structure according to an embodiment of the present invention, and FIG. 2 is a schematic sectional view along the tangent line A-A′ (channel length direction) in FIG. 1.

As shown in FIGS. 1 to 2, a high-voltage semiconductor structure 1, such as a field drift metal oxide semiconductor (FDMOS) transistor, is provided, which includes a substrate 100, such as a silicon substrate. In this embodiment, the substrate 100 has a first conductivity type, such as a P-type. In the substrate 100, there is a high-voltage well PW, wherein in this embodiment, the high-voltage well PW has a first conductivity type, for example, P-type. According to an embodiment of the present invention, a source drift region SF and a drain drift region DF are arranged in the high-voltage well PW, wherein both the source drift region SF and the drain drift region DF have a second conductivity type, for example, N-type. However, the conductive patterns of the above elements are only one example of the present invention, and the present invention is not limited to this.

In addition, the substrate 100 also includes a gate structure 102, in which the gate structure 102 may include a gate electrode GE, a gate dielectric layer GI under the gate electrode GE, and spacers SP surrounding the gate electrode GE. In FIG. 1, for the sake of simplicity, the gate structure 102 represents the sum of the gate electrode GE, the gate dielectric layer GI and the spacers SP. In addition, the gate structure 102 is connected to a gate terminal G for controlling the turning-on or turning-off of the gate of the high-voltage semiconductor structure 1.

The range of the substrate 100 directly under the gate structure 102 is, for example, a P-type doped region, and the doped region directly under the gate structure 102 is defined as a gate doped region 120, wherein the range of the gate doped region 120 is rectangular when viewed from the top, and the position of the gate doped region 120 partially overlaps with the source drift region SF and the drain drift region DF. Especially, four corners C of the gate doped region 120 overlap with the source drift region SF or the drain drift region DF. In some embodiments, the gate doped region 120 can also be regarded as a part of the high-voltage well PW. In this embodiment, both the gate doped region 120 and the high-voltage well PW have the first conductivity type (P-type).

In the source drift region SF and the drain drift region DF, there are respectively a heavily doped source region 111 and a heavily doped drain region 112, wherein the heavily doped source region 111 and the heavily doped drain region 112 can be N+ doped regions. In addition, a source terminal S and a drain terminal D are included to electrically connect the heavily doped source region 111 and the heavily doped drain region 112, respectively. In addition, in this embodiment, the distance between the source drift region SF and the drain drift region DF is defined as L1, which represents the channel length of the high-voltage semiconductor device.

In addition, the substrate 100 is provided with a plurality of shallow trench isolation STI's, which are used for isolating elements or defining the position of drift regions or doped regions. The distribution of shallow trench isolation STI can be shown with reference to FIG. 2. Part of the shallow trench isolation STI is located in the source drift region SF and the drain drift region DF, and the shallow trench isolation STI located in the source drift region SF and the drain drift region DF here is used to prolong the current path. More specifically, the operating voltage of the high-voltage semiconductor structure 1 of the present invention is relatively large (usually more than 10 volts), so a relatively large electric field is easily generated around the gate structure 102 during operation, and at this time, current may penetrate through the gate dielectric layer GI and further affect the gate structure 102. Therefore, the shallow trench isolation STI located in the source drift region SF and the drain drift region DF here has the function of prolonging the current path (making the current pass under the shallow trench isolation STI to avoid directly passing through the gate dielectric layer GI). In addition, for the sake of simplicity, the position of shallow trench isolation STI is not drawn in FIG. 1.

In addition, this embodiment includes a frame-shaped ion well 130. The frame-shaped ion well 130 has a first conductivity type, for example, P-type. It also includes a heavily doped region 131 arranged in the frame-shaped ion well 130, which can be a P+ doped region according to the embodiment of the present invention. The frame-shaped ion well 130 surrounds the source drift region SF, the drain drift region DF and the gate structure 102. The frame-shaped ion well 130 described here can be regarded as a guard ring, and its main function is to connect a signal (such as a stable signal or a grounding signal) to achieve the effects of absorbing the noise of the high-voltage semiconductor structure 1 and stabilizing the voltage.

In operation, when a signal (such as a voltage source) is connected to the source terminal S and the drain terminal D, and a threshold voltage (Vth) is applied to the gate terminal G, a current can flow from the source terminal S through a channel region (not shown) below the gate structure 102 to the drain terminal D. The above behavior is called turning on the high-voltage semiconductor structure 1. However, in the actual operating state, due to the high applied voltage of the high-voltage semiconductor structure 1, the channel boundary of the gate doped region 120 of the high-voltage semiconductor structure 1 may face Kink effect. The so-called Kink effect means that at high drain voltage, the carriers near the drain terminal will multiply, so that the drain current will increase rapidly with the drain voltage. This will cause the current to flow from the drain terminal D to the source terminal S before the gate terminal G reaches the threshold voltage. Among them, the Kink effect is particularly common at the boundary of the doped region (the channel boundary). For example, near the upper edge E3 and the lower edge E4 of the gate doped region 120 shown in FIG. 1, the Kink effect is easy to occur, resulting in the unexpected turning-on of the high-voltage semiconductor structure at the channel boundary. In order to clearly show the characteristics of the present invention, in the following paragraphs, the region of the gate doped region 120 adjacent to the upper edge E3 or the lower edge E4 is defined as “channel boundary region R1”.

The above Kink effect is mainly caused by the insufficient doping concentration of the gate doped region 120 at the channel boundary region R1 and the thin thickness of the gate dielectric layer GI. In order to solve the Kink effect, in this embodiment, an additional doped region 140 is formed near the upper edge E3 and the lower edge E4 of the gate doped region 120 (i.e., the channel boundary region R1), wherein the additional doped region 140 also has a first conductivity type, for example, P-type. In this embodiment, the doping concentration of the additional doped region 140 may be similar to or the same as that of the frame-shaped ion well 130, and the depth of the additional doped region 140 is deeper than the bottom surface of the shallow trench isolation STI. The additional doped region 140 in the channel boundary region R1 of the doped region 120 can supplement the doping concentration of the channel boundary region R1, and prevent the Kink effect from occurring in the channel boundary region R1 (i.e., at the upper edge E3 and the lower edge E4 of the gate doped region 120), which means that the probability of the Kink effect can be reduced.

However, although forming the additional doped region 140 can reduce Kink effect, the additional doped region 140 occupies a certain area of the whole high-voltage semiconductor structure. With the progress of semiconductor manufacturing process, the size of each component is getting smaller and smaller. That is to say, as the area of the high-voltage semiconductor structure 1 becomes smaller and smaller, it will be more difficult to form the additional doped region 140. In addition, the applicant found that forming the additional doped region 140 will affect the threshold voltage and turn-on current of the gate terminal G, and the change of the threshold voltage of the gate terminal G is particularly obvious when the area of the high-voltage semiconductor structure 1 is smaller. According to the applicant's experiments, the changing range of the critical voltage can reach about 50%. Therefore, the formation of additional doped region 140 will change the threshold voltage of gate terminal G, which is not conducive to the maintenance of semiconductor manufacturing yield.

Therefore, in another embodiment of the present invention, an improved high-voltage semiconductor structure is provided to solve the above-mentioned problems such as the decrease of process yield due to the formation of additional doped regions 140 on both sides of the gate doped region 120. Details are shown in the following paragraphs.

The following description will detail the different embodiments of the high-voltage semiconductor structure and the manufacturing method of the present invention. To simplify the description, the following description will detail the dissimilarities among the different embodiments and the identical features will not be redundantly described. In order to compare the differences between the embodiments easily, the identical components in each of the following embodiments are marked with identical symbols.

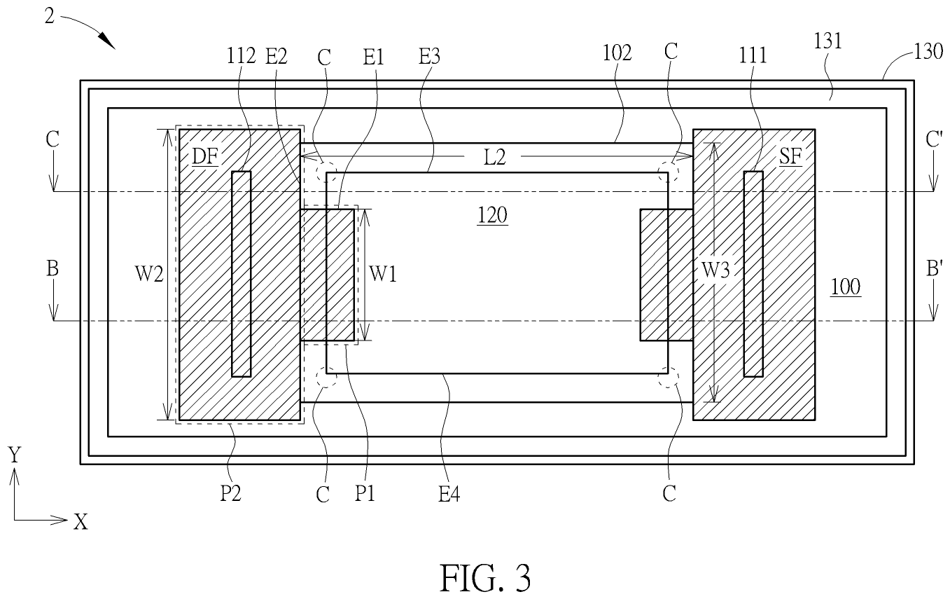

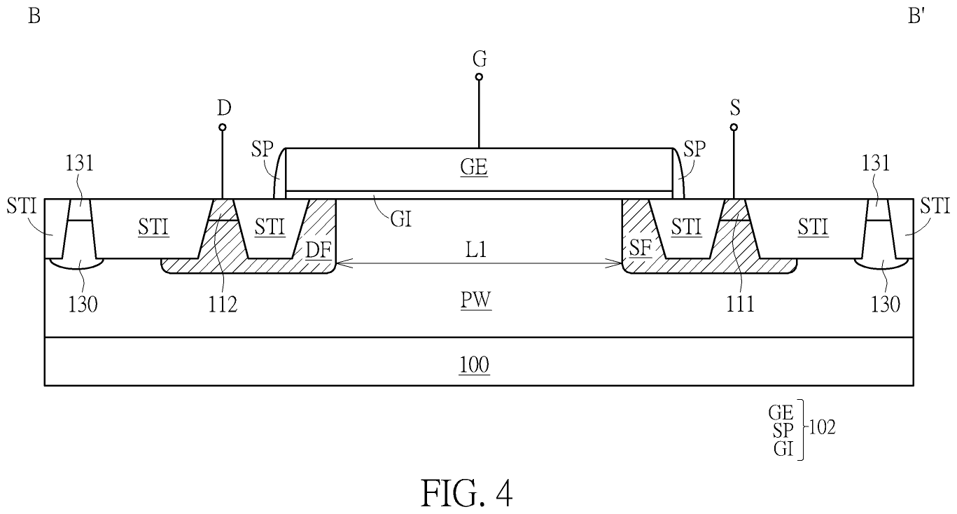

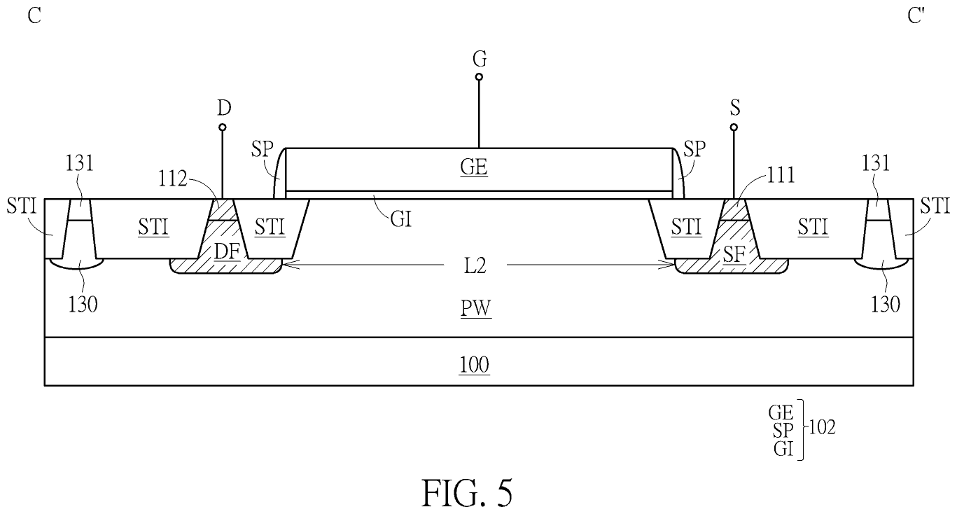

Please refer to FIGS. 3 to 5, FIG. 3 is a schematic layout diagram of the high-voltage semiconductor structure according to the second embodiment of the present invention, FIG. 4 is a schematic cross-sectional view of the high-voltage semiconductor structure according to FIG. 3 along section line B-B′, and FIG. 5 is a schematic cross-sectional view of the high-voltage semiconductor structure according to FIG. 3 along section line C-C′. As shown in FIGS. 3 to 5, a high-voltage semiconductor structure 2 is provided. Most of the elements in the high-voltage semiconductor structure 2 are the same as those in the high-voltage semiconductor structure 1 in the first embodiment, such as the substrate 100, the high-voltage well PW, the source drift region SF, the drain drift region DF, the heavily doped source region 111, the heavily doped drain region 112, the gate structure 102, the shallow trench isolation STI, the frame-shaped ion well 130 and the heavily doped region 131. Unless specifically mentioned, these elements have the same or similar material composition as those described in the first preferred embodiment and can be formed by the same process. Therefore, these repeated elements are not detailed here.

The difference between this embodiment and the first embodiment is that the additional doped region 140 in the first embodiment is not included beside the gate doped region 120, and the shapes of the source drift region SF and the drain drift region DF in this embodiment are different from those in the first embodiment. More specifically, as shown in FIG. 1, in the first embodiment, the source drift region SF and the drain drift region DF are rectangular with four corners C. However, as shown in FIG. 3, in this embodiment, two corners of the source drift region SF and the drain drift region DF recede inward, so that the source drift region SF and the drain drift region DF present a “T shape”. Since both the source drift region SF and the drain drift region DF are symmetrical in shape, only the drain drift region DF will be described below, and the source drift region SF will not be repeated because of its symmetrical shape.

As shown in FIG. 3, the drain drift region DF has a shape similar to a T-shape, which can be divided into a first part P1 and a second part P2, wherein the first part P1 and the second part P2 are in direct contact. In addition, the width W1 of the first part P1 is smaller than the width W2 of the second part P2 (the width W1 and the width W2 here refer to the length along the Y direction, as shown in FIG. 3). A first edge E1 is defined on the first part P1 and a second edge E2 is defined on the second part P2, wherein the first edge E1 extends along the X direction and the second edge E2 extends along the Y direction, and the first edge E1 is directly adjacent to and preferably perpendicular to the second edge E2. In some embodiments, the length of the first edge E1 is 0.2 to 1.6 microns, and the length of the second edge E2 is 0.2 to 1.2 microns. Therefore, from another point of view, the shape of the drain drift region DF in this embodiment can be obtained by cutting two rectangle corners of the rectangular drain drift region DF in the first embodiment, and each rectangle corner has the length and width of the second edge E2 and the first edge E1 respectively.

It is worth noting that the gate doped region 120 is also rectangular and has four corners C from the top view. Another feature of this embodiment is that the drain drift region DF and the source drift region SF have a T-shape from the top view and do not overlap with the four corners C of the gate doped region 120. In contrast, the drain drift region DF and the source drift region SF of the first embodiment of the present invention overlap with the four corners C of the gate doped region 120 (as shown in FIG. 1).

In practice, two corners of the drain drift region DF and the source drift region SF in this embodiment retreat inward, so the distance between the drain drift region DF and the source drift region SF becomes longer near the boundary of the gate doped region 120 (corresponding to the upper edge E3 and the lower edge E4 of the gate doped region 120). Please refer to FIG. 4 and FIG. 5, wherein FIG. 4 is a schematic cross-sectional view of the high-voltage semiconductor structure according to FIG. 3 along section line B-B′, and FIG. 5 is a schematic cross-sectional view of the high-voltage semiconductor structure according to FIG. 3 along section line C-C′. As can be seen from FIG. 3, in this embodiment, the distance between the drain drift region DF and the source drift region SF in the horizontal direction of the upper edge E3 in the top view is defined as L2, where L2 can be regarded as the effective channel length at the boundary, and the length L2 is greater than the length L1 shown in FIG. 1.

As shown in FIG. 5, along the section line C-C′ (the direction aligned with the upper edge E3 in the top view), the boundary of the drain drift region DF (corresponding to the second edge E2 in FIG. 3) and the boundary of the source drift region SF are located directly below the shallow trench isolation STI. Therefore, at the section line C-C′ of the high-voltage semiconductor structure 2 of this embodiment, the distance between the drain drift region DF and the source drift region SF is longer, resulting in a longer effective channel length. Therefore, under high operating voltage, it is not easy for the current to directly penetrate from the drain drift region DF to the source drift region SF (or vice versa) in the vicinity of the boundary of the gate doped region 120. In other words, the occurrence probability of Kink effect can be reduced.

In this embodiment, by changing the shapes of the drain drift region DF and the source drift region SF, the distance between the drain drift region DF and the source drift region SF in the boundary region of the gate doped region 120 becomes longer, thereby actively reducing Kink effect. Therefore, this embodiment does not need to form the additional doped region 140 as described in the first embodiment. In this way, the disadvantages of the first embodiment can also be avoided, such as the formation of additional doped regions 140 will increase the process difficulty and affect the critical voltage.

Based on the above description and drawings, the present invention provides a high-voltage semiconductor structure 2, which comprises a substrate 100 with a first conductivity type (e.g., P-type), a gate structure 102 located on the substrate 100, a source drift region SF and a drain drift region DF located in the substrate 100 on both sides of the gate structure 102, respectively, wherein from the top view, the source drift region SF and the drain drift region DF respectively comprise a first part P1 and a second part P2, wherein a width W1 of the first part P1 is smaller than a width W2 of the second part P2, and the first part P1 is directly connected with the second part P2, so that the source drift region SF and the drain drift region DF are T-shaped when viewed from the top, and the source drift region SF and the drain drift region DF have a second conductivity type (for example, N-type).

In some embodiments of the present invention, the first part P1 of the source drift region SF is close to the gate structure 102, and the second part P2 of the source drift region SF is far away from the gate structure 102 (from the top view).

In some embodiments of the present invention, a gate doped region 120 is located in the substrate below the gate structure 102, wherein the gate doped region 120 is rectangular with four corners C when viewed from the top, and the gate doped region 120 has the first conductivity type (e.g., P-type).

In some embodiments of the present invention, the four corners C of the gate doped region 120 do not overlap the source drift region SF and the drain drift region DF when viewed from the top (as shown in FIG. 3, the T-shaped source drift region SF and the drain drift region DF do not overlap the four corners C of the gate doped region 120).

In some embodiments of the present invention, the source drift region SF, the gate structure 102 and the drain drift region DF are arranged along a first direction (X direction), and a second direction (Y direction) is defined to be perpendicular to the first direction.

In some embodiments of the present invention, the first part P1 of the drain drift region DF has a first edge E1 extending along the first direction (X direction), which is directly adjacent to the second part P2 of the drain drift region DF, wherein the length of the first edge E1 is 0.2 microns to 1.6 microns.

In some embodiments of the present invention, the second part P2 of the drain drift region DF has a second edge E2 extending along the second direction (Y direction), and the second edge E2 is directly adjacent to the first part P1 of the drain drift region DF, wherein the length of the second edge P2 is 0.2 microns to 1.2 microns.

In some embodiments of the present invention, a shallow trench isolation STI is located in the substrate 100, wherein the second edge E2 of the second part P2 of the source drift region SF is located below the shallow trench isolation STI from a cross-sectional view.

In some embodiments of the present invention, a frame-shaped ion well 130 is further included around the gate structure 102, the source drift region SF and the drain drift region DF, and the frame-shaped ion well 130 has the first conductivity type (for example, P-type).

In some embodiments of the present invention, the gate doped region 120 includes a third edge (e.g., the upper edge E3) adjacent to the frame-shaped ion well 130, and the third edge E3 extends along the first direction, wherein along the second direction (Y direction), the substrate 100 between the third edge E3 and the frame-shaped ion well 130 does not include other doped regions (that is, in the second embodiment of the present invention, there is no need to form an additional doped region next to the upper edge E3, so there is no other doped region between the upper edge E3 and the nearest frame-shaped ion well 130).

In some embodiments of the present invention, the first part P1 of the source drift region SF partially overlaps the gate doped region 120 (near the central channel) when viewed from the top.

In some embodiments of the present invention, an area of the gate doped region 120 is smaller than an area of the gate structure 102 when viewed from the top.

In some embodiments of the present invention, the width W1 of the first part P1 of the drain drift region DF is smaller than a width W3 of the gate structure 102, and the width W2 of the second part p2 of the drain drift region DF is larger than the width of the gate structure 102.

In some embodiments of the present invention, a heavily doped source region 111 is located on the source drift region SF, and a heavily doped drain region 112 is located on the drain drift region DF. The heavily doped source region 111 and the heavily doped drain region 112 contain the second conductivity type (e.g., N-type).

The invention also provides a method for forming a high-voltage semiconductor structure, which comprises providing a substrate 100 with a first conductivity type (for example, P-type), forming a gate structure 102 on the substrate 100, forming a source drift region SF and a drain drift region DF in the substrate 100 on both sides of the gate structure 102, wherein from the top view, the source drift region SF and the drain drift region DF respectively comprise a first part P1 and a second part P2, wherein a width W1 of the first part P1 is smaller than a width W2 of the second part P2, and the first part P1 is directly connected with the second part P2, so that the source drift region SF and the drain drift region DF are T-shaped when viewed from the top, and the source drift region SF and the drain drift region DF have a second conductivity type (for example, N-type).

The invention is characterized by providing a high-voltage semiconductor structure and a manufacturing method thereof. The source drift region and the drain drift region contained therein have a shape similar to a T-shape from the top view or have a notched corner. Because of the notched corner, the effective channel length between the source drift region and the drain drift region becomes longer at the boundary part parallel to the gate doped region, so that Kink effect can be reduced without forming additional doped regions, and the stability of the high-voltage semiconductor structure and the process yield can be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A high-voltage semiconductor structure comprising:
a substrate having a first conductivity type;
a gate structure located on the substrate;
a source drift region and a drain drift region located in the substrate at two sides of the gate structure respectively, wherein from a top view, the source drift region and the drain drift region respectively comprise a first part and a second part, a width of the first part is smaller than a width of the second part, the first part is directly connected with the second part, and the source drift region and the drain drift region are T-shaped from the top view, and the source drift region and the drain drift region have a second conductivity type.

2. The high-voltage semiconductor structure according to claim 1, wherein the first part of the drain drift region is close to the gate structure and the second part is far away from the gate structure.

3. The high-voltage semiconductor structure according to claim 1, further comprising a gate doped region located in the substrate below the gate structure, wherein the gate doped region is rectangular with four corners when viewed from the top, and the gate doped region has the first conductivity type.

4. The high-voltage semiconductor structure according to claim 3, wherein the four corners of the gate doped region do not overlap with the source drift region and the drain drift region when viewed from the top.

5. The high-voltage semiconductor structure according to claim 3, wherein the source drift region, the gate structure and the drain drift region are arranged along a first direction (X direction), and a second direction (Y direction) is defined to be perpendicular to the first direction.

6. The high-voltage semiconductor structure according to claim 5, wherein the first part of the drain drift region has a first edge extending along the first direction, and the first edge is directly adjacent to the second part of the drain drift region, wherein a length of the first edge is 0.2 to 1.6 microns.

7. The high-voltage semiconductor structure according to claim 5, wherein the second part of the drain drift region has a second edge extending along the second direction, and the second edge is directly adjacent to the first part of the drain drift region, wherein a length of the second edge is 0.2 microns to 1.2 microns.

8. The high-voltage semiconductor structure according to claim 7, further comprising a shallow trench isolation located in the substrate, wherein the second edge of the second part of the source drift region is located below the shallow trench isolation in a sectional view.

9. The high-voltage semiconductor structure according to claim 5, further comprising a frame-shaped ion well surrounding the gate structure, the source drift region and the drain drift region, the frame-shaped ion well having the first conductivity type.

10. The high-voltage semiconductor structure according to claim 9, wherein the gate doped region comprises a third edge adjacent to the frame-shaped ion well, and the third edge extends along the first direction, wherein there is no other doped regions included in the substrate between the third edge and the frame-shaped ion well along the second direction.

11. The high-voltage semiconductor structure according to claim 3, wherein the first part of the source drift region partially overlaps the gate doped region when viewed from the top.

12. The high-voltage semiconductor structure according to claim 3, wherein an area of the gate doped region is smaller than an area of the gate structure when viewed from the top.

13. The high-voltage semiconductor structure according to claim 1, wherein the width of the first part of the drain drift region is smaller than a width of the gate structure when viewed from the top, and the width of the second part of the drain drift region is larger than the width of the gate structure.

14. The high-voltage semiconductor structure according to claim 1, further comprising a heavily doped source region on the source drift region and a heavily doped drain region on the drain drift region, wherein the heavily doped source region and the heavily doped drain region comprise the second conductivity type.

15. A method for forming a high-voltage semiconductor structure, comprising:
providing a substrate with a first conductive type;
forming a gate structure on the substrate;
forming a source drift region and a drain drift region in the substrate at two sides of the gate structure respectively, wherein the source drift region and the drain drift region respectively comprise a first part and a second part when viewed from the top, and a width of the first part is smaller than a width of the second part, and the first part is directly connected with the second part, wherein the source drift region and the drain drift region are T-shaped when viewed from the top, and the source drift region and the drain drift region have a second conductivity type.

16. The method for forming a high-voltage semiconductor structure according to claim 15, wherein the first part of the source drift region and the drain drift region are close to the gate structure, while the second part of the source drift region and the drain drift region are far away from the gate structure.

17. The method for forming a high-voltage semiconductor structure according to claim 15, further comprising forming a gate doped region in the substrate below the gate structure, wherein the gate doped region is rectangular and has four corners when viewed from the top, and the gate doped region has the first conductivity type.

18. The method for forming a high-voltage semiconductor structure according to claim 17, wherein the four corners of the gate doped region do not overlap with the source drift region and the drain drift region when viewed from the top.

19. The method for forming a high-voltage semiconductor structure according to claim 15, wherein the width of the first part of the source drift region is smaller than a width of the gate structure when viewed from the top, and the width of the second part of the source drift region is larger than the width of the gate structure.

20. The method for forming a high-voltage semiconductor structure according to claim 15, further comprising forming a frame-shaped ion well around the gate structure, the source drift region and the drain drift region, wherein the frame-shaped ion well has the first conductivity type.
